(19) United States
(12) Patent Application Publication
(10) Pub. No.: US 2026/0104651 A1
(43) Pub. Date: Apr. 16, 2026

(54) CONTROL APPARATUS, POSITIONING APPARATUS, LITHOGRAPHY APPARATUS, AND ARTICLE MANUFACTURING METHOD

(71) Applicant: CANON KABUSHIKI KAISHA, Tokyo (JP)

(72) Inventors: TAKUMI HASHIMOTO, Tokyo (JP); HIROKAZU KUSAYANAGI, Tochigi (JP); YASUNOBU ASAKURA, Tochigi (JP)

(21) Appl. No.: 19/352,176

(22) Filed: Oct. 7, 2025

(30) Foreign Application Priority Data
Oct. 15, 2024 (JP) 2024-180338

(51) Int. Cl. G03F 7/00; G05B 23/02

(52) U.S. Cl. CPC G03F 7/70725; G03F 7/70508; G03F 7/70525; G05B 23/0275; G05B 2223/02

(57) ABSTRACT

Control apparatuses, positioning apparatuses, lithography apparatuses, article manufacturing methods, and storage mediums are provided herein. A control apparatus controls an object based on a feedforward manipulated variable generated by a feedforward controller. The apparatus includes a determinator that operates to determine a gain of the feedforward controller based on a control error data string indicating a change in control error in the object and a response data string indicating a response characteristic of the object when a specific manipulated variable is provided to the object. The determinator generates a representative value data string constituted by representative values of control errors of the object at respective times based on a plurality of control error data strings acquired over a plurality of times and determines the gain based on the representative value data string and the response data string.

### BACKGROUND

### Field of the Technology

The present disclosure relates to one or more embodiments of a control apparatus, a positioning apparatus, a lithography apparatus, and an article manufacturing method.

### Description of the Related Art

In a control system represented by a two-degree-of-freedom control system, the response performance corresponding to a target value depends on the modelization accuracy of an object. Although various modelization techniques have been tried, each technique cannot implement perfectly accurate modelization and hence cannot be free from modelization errors. In addition, the higher the performance required for a control system, the higher the modelization accuracy required for an object, resulting in a larger load on modelization. Japanese Patent Laid-Open No. 2013-218496 discloses a method of implementing feedforward control that can implement accurate control without requiring any modelization of the object.

Feedforward control that performs control based on prediction can be expected to implement an improvement in control accuracy with respect to a disturbance environment with high reproducibility. On the other hand, feedforward control is difficult in maintaining a high improvement effect in an environment in which prediction tends to become significantly wrong, that is, a disturbance environment including a disturbance with low reproducibility.

The method disclosed in Japanese Patent Laid-Open No. 2013-218496 can implement accurate control without requiring the modelization of an object by determining a feedforward manipulated variable based on the relationship between the manipulated variable provided to the object and the output response and the control error of the object. However, in an environment including a disturbance with low reproducibility, since the reproducibility of the control error of an object used for the determination of a feedforward manipulated variable is low, the feedforward manipulated variable calculated by the method disclosed in Japanese Patent Laid-Open No. 2013-218496 may not be sometimes optimal.

### SUMMARY

One or more aspects of the present disclosure include at least one embodiment of a technique advantageous in improving the control accuracy by feedforward control even under an environment including a disturbance with low reproducibility.

The present disclosure includes one or more embodiments of a control apparatus that operates to control an object based on a feedforward manipulated variable generated by a feedforward controller, where the control apparatus may include a determinator that operates to: (i) determine a gain of the feedforward controller based on a control error data string indicating a change in a control error of the object and a response data string indicating a response characteristic of the object in a case where a specific manipulated variable is provided to the object; and (ii) generate a representative value data string constituted by representative values of control errors of the object at respective times based on a plurality of control error data strings acquired over a plurality of times and determine the gain based on the representative value data string and the response data string.

According to other aspects of the present disclosure, one or more additional control apparatuses, one or more positioning apparatuses, one or more lithography apparatuses, one or more methods, one or more article manufacturing methods, and one or more storage mediums are discussed herein. Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate non-exhaustive embodiments of the present disclosure, and together with the description, serve to explain one or more principles of one or more of the embodiments.

FIG. 1 is a schematic view showing at least one embodiment example of an arrangement of an exposure apparatus according to one or more aspects of the present disclosure;

FIG. 2A is a block diagram showing at least an arrangement example of at least one embodiment of a control apparatus that controls an object based on a feedforward manipulated variable according to one or more aspects of the present disclosure;

FIG. 2B is a block diagram showing at least an additional arrangement example of at least one embodiment of a control apparatus that controls the object based on a feedforward manipulated variable according to one or more aspects of the present disclosure;

FIG. 3A is a block diagram for explaining at least one embodiment of a gain determination processing of determining a gain of a feedforward controller according to one or more aspects of the present disclosure;

FIG. 3B is a block diagram for explaining at least one embodiment of a gain determination processing of determining a gain of the feedforward controller according to one or more aspects of the present disclosure;

FIG. 3C is a block diagram for explaining at least one embodiment of a gain determination processing of determining a gain of the feedforward controller according to one or more aspects of the present disclosure;

FIGS. 4A and 4B are graphs showing at least one embodiment example of the moving standard deviations of control errors in at least one embodiment of an original plate stage mechanism in a case where feedforward manipulated variables are provided to the original plate stage mechanism of at least one embodiment of an exposure apparatus according to one or more aspects of the present disclosure;

FIG. 5 is a graph showing, on a time-series basis, the reproducibility of control errors in at least one embodiment of an original plate stage mechanism from time 0 to time 1000 in a time interval of exposure processing according to one or more aspects of the present disclosure;

FIG. 6 is a block diagram showing at least one embodiment example of an arrangement of a control apparatus according to one or more aspects of the present disclosure;

FIG. 7 is a flowchart exemplarily showing at least one embodiment of a procedure in a method of determining the gain of a feedforward controller according to one or more aspects of the present disclosure;

FIG. 8 is a flowchart exemplarily showing details of at least one embodiment of a step of acquiring a representative value data string of control errors according to one or more aspects of the present disclosure;

FIG. 9 is a flowchart exemplarily showing details of at least one embodiment of a processing of determining an accumulation number of control error data strings according to one or more aspects of the present disclosure;

FIG. 10 is a flowchart exemplarily showing the details of at least one embodiment of a step of acquiring a response data string according to one or more aspects of the present disclosure;

FIGS. 11A and 11B are graphs exemplarily showing at least one embodiment of moving standard deviations of control errors in at least one embodiment of an original plate stage mechanism in a case where feedforward manipulated variables gₙΔf(t+tₙ) are provided to the original plate stage mechanism of at least one embodiment of an exposure apparatus according to one or more aspects of the present disclosure;

FIG. 12 is a block diagram showing at least one additional embodiment example of an arrangement of a control apparatus according to one or more aspects of the present disclosure;

FIG. 13 is a flowchart exemplarily showing at least one embodiment of details of a step of acquiring a representative value data string of a response characteristic according to one or more aspects of the present disclosure;

FIG. 14 is a block diagram showing at least one further embodiment example of an arrangement of a control apparatus according to one or more aspects of the present disclosure;

FIG. 15 is a flowchart exemplarily showing at least one embodiment of details of a step of acquiring a representative value data string of control errors according to one or more aspects of the present disclosure;

FIG. 16 is a block diagram showing at least another embodiment example of an arrangement of a control apparatus according to one or more aspects of the present disclosure; and

FIG. 17 is a flowchart exemplarily showing at least one embodiment of details of a step of acquiring a representative value data string of control errors according to one or more aspects of the present disclosure.

### DESCRIPTION OF THE EMBODIMENTS

Hereinafter, embodiments will be described in detail with reference to the attached drawings. Note, the following embodiments are not intended to limit the scope of the claims and/or any feature(s) or aspect(s) of the present disclosure. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

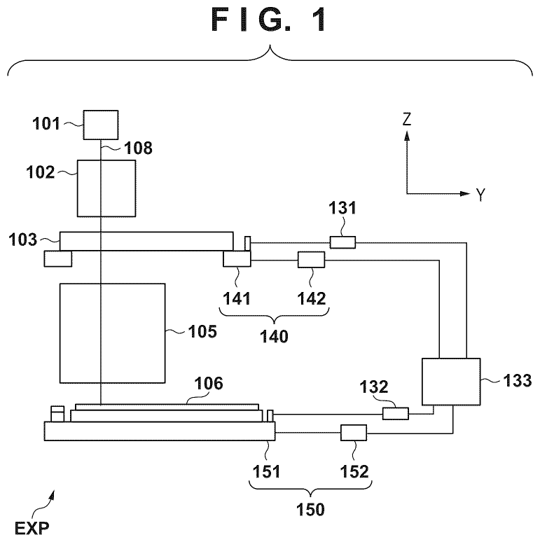

FIG. 1 is a schematic view showing an arrangement of at least one embodiment of an exposure apparatus EXP according to one or more aspects of the present disclosure. The exposure apparatus EXP is a lithography apparatus that transfers the pattern of an original plate 103 onto a substrate 106. In this case, the exposure apparatus EXP is a step-and-scan exposure apparatus (scanning exposure apparatus). Note, however, that the exposure apparatus EXP may be an exposure apparatus based on another exposure scheme such as a step-and-repeat scheme. The exposure apparatus EXP may include an illumination light source 101, an illumination optical system 102, an original plate stage mechanism 140, a projection optical system 105, a substrate stage mechanism 150, detectors 131 and 132, and a control device 133.

The illumination light source 101 may include, for example, a mercury lamp, a laser light source, an EUV light source, or an LED light source. The illumination light source 101 is constituted by arbitrary types and number of light sources. The illumination optical system 102 is an optical system that illuminates an illumination region of the original plate 103 by using exposure light 108 from the illumination light source 101. The illumination region may have a shape elongated in the X-axis direction orthogonal to the Y-axis direction as the scanning direction. The illumination region preferably has an arc shape in some case depending on the type of the projection optical system 105. The illumination optical system 102 may include, for example, a beam shaping optical system that shapes a cross-sectional shape of light from the illumination light source 101 and an optical integrator that forms many secondary light sources for illuminating the original plate 103 with a uniform illuminance distribution.

The original plate stage mechanism 140 may include an original plate stage 141 having an original plate chuck that holds the original plate 103 and an original plate stage driving mechanism 142 that drives the original plate stage 141 in the X-axis direction, the Y-axis direction, and the Z-axis direction and the rotation of the original plate stage 141 about each axis. A surface of the original plate 103 or the substrate 106 is placed parallel to an X-Y plane. The scanning direction of the original plate 103 and the substrate 106 is defined as a Y-axis direction, and a direction perpendicular to an X-Y plane is defined as a Z-axis direction. The original plate 103 has a pattern to be transferred onto the substrate 106. The exposure light 108 illuminating the original plate 103 is diffracted by the original plate 103 (its pattern) and projected on the substrate 106 by the projection optical system 105. The original plate 103 and the substrate 106 are placed in an optically conjugated relationship. In this embodiment, since the exposure apparatus EXP is a step-and-scan exposure apparatus, the pattern of the original plate 103 is transferred onto the substrate 106 by synchronously scanning the original plate 103 and the substrate 106. The original plate 103 may also be called a reticle or mask.

The projection optical system 105 is an optical system that projects the pattern of the original plate 103 onto the substrate 106. As the projection optical system 105, a refracting system, a catadioptric system, or a reflecting system may be used. The pattern of the original plate 103 is projected and transferred onto the substrate 106. The substrate 106 is coated with a photoresist (photosensitive material). The substrate 106 may be, for example, a semiconductor wafer or a glass plate. The substrate stage mechanism 150 may include a substrate stage 151 having a substrate chuck for holding the substrate 106 and a substrate stage driving mechanism 152 that drives the substrate stage 151 in the X-axis direction, the Y-axis direction, and the Z-axis direction and the rotation of the substrate stage 151 about each axis.

The detector 131 detects the position of the original plate stage 141 and provides the control device 133 with the detected value of the position of the original plate stage 141. The detector 131 may include, for example, a laser interferometer, a laser scale, or an encoder. The detector 132 detects the position of the substrate stage 151 and provides the control device 133 with the detected value of the position of the substrate stage 151. The detector 132 may include, for example, a laser interferometer, a laser scale, or an encoder. The original plate stage mechanism 140, the detector 131, and the control device 133 may constitute an original plate positioning apparatus that positions the original plate 103. The substrate stage mechanism 150, the detector 132, and the control device 133 may constitute a substrate positioning apparatus that positions the substrate 106. The control device 133 may be implemented by a PLD (Programmable Logic Device) such as an FPGA (Field Programmable Gate Array), a general-purpose or dedicated computer incorporating an ASIC (Application Specific Integrated Circuit) and programs, or a combination of all or some of the above constituent elements.

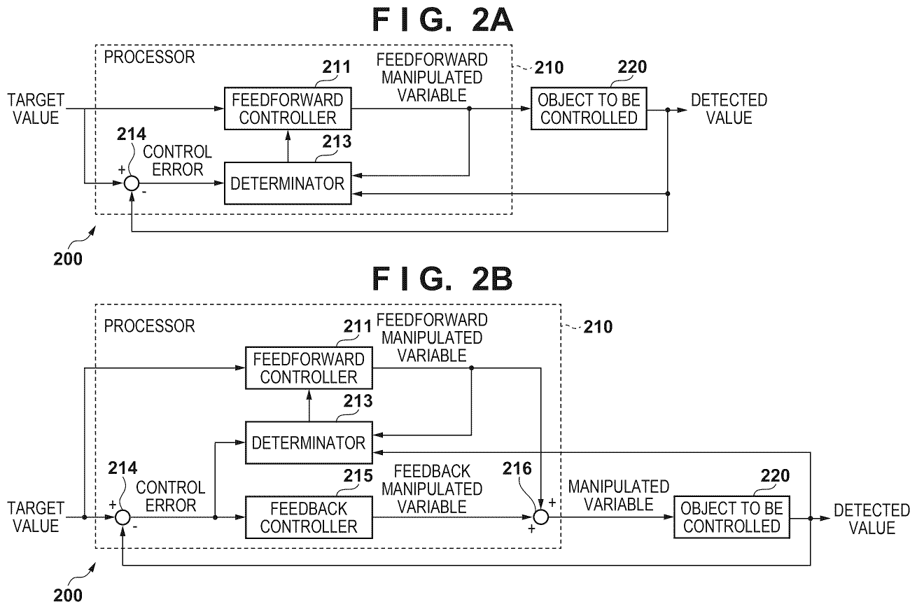

FIG. 2A shows at least one embodiment arrangement example of a control apparatus 200 that controls an object 220 based on a feedforward manipulated variable. The control apparatus 200 according to the at least one embodiment arrangement example includes a feedforward control system. The control apparatus 200 according to the at least one embodiment arrangement example may include, for example, a processor 210 and the object 220 that is controlled by the processor 210. The processor 210 may be implemented by, for example, a PLD such as an FPGA, a general-purpose or dedicated computer incorporating an ASIC and programs, or a combination of all or some of the above constituent elements. The processor 210 may be incorporated in the control device 133. For example, the object 220 may be the original plate stage mechanism 140 and the detector 131, and the detected value of the position of the original plate stage 141 in the original plate stage mechanism 140 is provided by the detector 131. Alternatively, the object 220 may be the substrate stage mechanism 150 and the detector 132, and the detected value of the position of the substrate stage 151 in the substrate stage mechanism 150 is provided by the detector 132.

The processor 210 may include, for example, a feedforward controller 211, a subtractor 214 that calculates the difference between a target value and a detected value, that is, a control error, and a determinator 213 that determines the gain (feedforward table) of the feedforward controller 211. The control apparatus 200 controls the object 220 by providing the object 220 with the feedforward manipulated variable generated by the feedforward controller 211 in accordance with a target value. The determinator 213 determines the gain of the feedforward controller 211 so as to make the object 220 follow a target value. The feedforward controller 211 may generate a feedforward manipulated variable by multiplying a target value with the gain of the feedforward controller 211. The determinator 213 may acquire a control error data string indicating a change in control error (output from the subtractor 214) of the object 220 while a predetermined target value is provided to the subtractor 214. The predetermined target value may be provided in a time-series data string. The determinator 213 may acquire the detected value data string output from the object 220, that is, a response data string indicating the response characteristic of the object 220, while the object 220 is provided with a specific manipulated variable for specifying a characteristic of the object 220. The determinator 213 may determine the gain of the feedforward controller 211 based on a control error data string and a response data string.

FIG. 2B shows at least an additional arrangement example of a control apparatus 200 that operates to control an object based on a feedforward manipulated variable. The control apparatus 200 according to at least the additional arrangement example includes a two-degree-of-freedom control system obtained by combining a feedforward control system and a feedback control system. The control apparatus 200 according to at least the additional embodiment may include, for example, the processor 210 and the object 220 that is controlled by the processor 210. The processor 210 may be implemented by, for example, a PLD such as an FPGA, a general-purpose or dedicated computer incorporating an ASIC and programs, or a combination of all or some of the above constituent elements. The processor 210 may be incorporated in the control device 133. For example, the object 220 may be the original plate stage mechanism 140 and the detector 131, and the detected value of the position of the original plate stage 141 in the original plate stage mechanism 140 is provided by the detector 131. Alternatively, the object 220 may be the substrate stage mechanism 150 and the detector 132, and the detected value of the position of the substrate stage 151 in the substrate stage mechanism 150 is provided by the detector 132.

The processor 210 may include, for example, the feedforward controller 211 that generates a feedforward manipulated variable in accordance with a target value and provides the feedforward manipulated variable to the object 220. In addition, the processor 210 may include the subtractor 214 that calculates the difference between the target value and the detected value, that is, a control error in the object 220 and a feedback controller 215 that generates a feedback manipulated variable corresponding to a control error and provides the feedback manipulated variable to the object 220. The processor 210 may also include an adder 216 that generates the sum of a feedforward manipulated variable and feedback manipulated variable as a manipulated variable for controlling the object 220. The processor 210 may further include the determinator 213 that determines the gain of the feedforward controller 211. The determinator 213 operates to determine the gain of the feedforward controller 211 so as to make the object 220 follow a target value. The feedforward controller 211 may generate a feedforward manipulated variable by multiplying a target value with the gain of the feedforward controller 211. The determinator 213 may acquire a control error data string indicating a change in control error (output from the subtractor 214) of the object 220 while a predetermined target value is provided to the subtractor 214. The predetermined target value may be provided in a time-series data string. The determinator 213 may acquire the detected value data string output from the object 220, that is, a response data string indicating the response characteristic of the object 220, while the object 220 is provided with a specific manipulated variable for specifying a characteristic of the object 220. The determinator 213 may determine the gain of the feedforward controller 211 based on a control error data string and a response data string.

Described below is at least one embodiment of an operation of determining the gain of the feedforward controller 211 in the control apparatus 200 according to at least the additional arrangement example exemplarily shown in FIG. 2B. This description may also be applied to the operation of determining the gain of the feedforward controller 211 in the control apparatus 200 according to the arrangement example exemplarily shown in FIG. 2A.

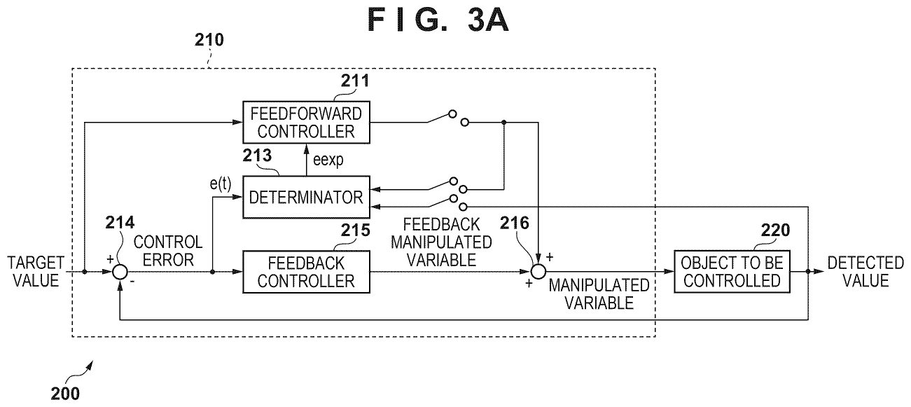

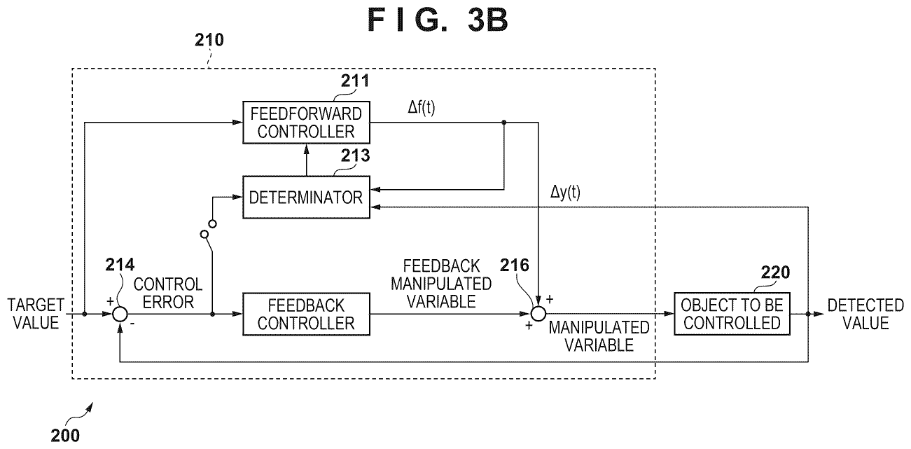

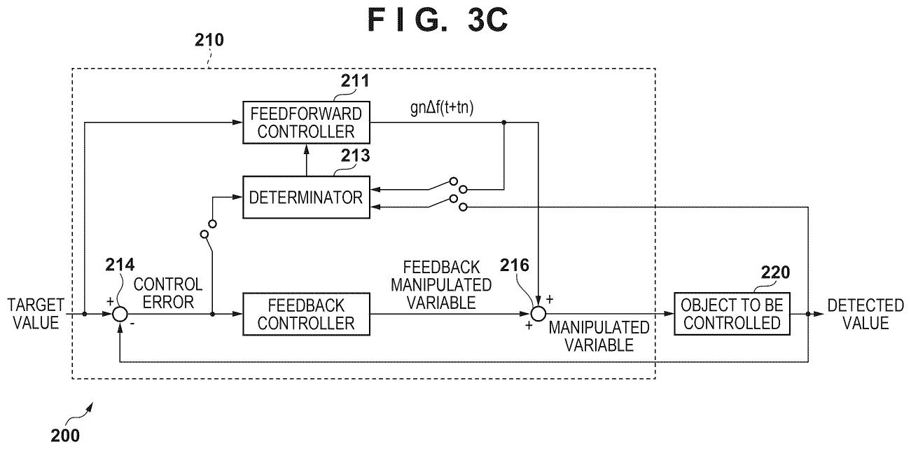

The gain determination processing of determining the gain of the feedforward controller 211 will be described below with reference to FIGS. 3A, 3B, and 3C. First of all, in the step shown in FIG. 3A, the determinator 213 acquires a control error e(t) in the object 220 which is output from the subtractor 214 while not providing any feedforward manipulated variable to the object 220 but providing a predetermined target value to the subtractor 214. The determinator 213 then determines a time interval in which predetermined processing (substrate exposure processing in this case) is performed and extracts a control error data string eₑₓₚ in the time interval of exposure processing from the control error e(t). If the time interval of exposure processing is from time 1 to time m, the extracted control error data string eₑₓₚ is expressed as equation (1):

$${e}_{exp} = \begin{matrix}[ {e}_{1} & {e}_{2} & … & {{e}_{m} ]}^{T}\end{matrix} \qquad ( 1 )$$

In the step shown in FIG. 3B, the feedforward controller 211 provides the object 220 with a specific manipulated variable Δf(t) as a feedforward manipulated variable at a given time to acquire a detected value data string as a response Δy(t) of the object 220. The determinator 213 then extracts a response data string y₀ in a time interval of exposure processing from the response Δy(t) of the object 220. The response data string y₀ is expressed as equation (2) given below. The specific manipulated variable Δf(t) may have, for example, an impulse waveform. Equation (2) is, as follows:

$${y}_{0} = \begin{matrix}[ {y}_{1 , 0} & {y}_{2 , 0} & … & {{y}_{m , 0} ]}^{T}\end{matrix} \qquad ( 2 )$$

The response data string y₀ is the detected value output from the object 220. On the other hand, the determinator 213 defines virtual data strings as other response data strings y₂, y₃, . . . , yₙ. More specifically, assuming that if the feedforward manipulated variable Δf(t) is provided to the object 220 first and then the same feedforward manipulated variable Δf(t) is provided to the object 220 after one sample period, the same response is obtained, the determinator 213 defines the response as y₁. Likewise, assuming that a response after two sample periods, a response after three sample periods, . . . , a response after n sample periods are defined as y₂, y₃, . . . , yₙ, y₀, y₁, . . . , yₙ are expressed as equation (3) given below:

$$\begin{matrix}[ {y}_{0} & {y}_{1} & … & {y}_{n} ] = [ \begin{matrix}{y}_{1 , 0} & {y}_{1 , 1} & … & {y}_{1 , n} \\ {y}_{2 , 0} & {y}_{2 , 1} & … & {y}_{2 , n} \\ ⋮ & ⋮ & ⋱ & ⋮ \\ {y}_{m , 0} & {y}_{m , 1} & … & {y}_{m , n}\end{matrix}\end{matrix} ] \qquad ( 3 )$$

In this case, assuming that a linear response is obtained from the object 220 with respect to an input, a response corresponding to a feedforward manipulated variable gΔf(t) is expressed as gΔy(t). Accordingly, if a gain after n sample periods is represented by gₙ, equation (4) given below holds:

$$\begin{matrix}[ {g}_{0} {y}_{0} & {g}_{1} {y}_{1} & … & {g}_{n} {y}_{n} ] = [ \begin{matrix}{g}_{0} {y}_{1 , 0} & {g}_{1} {y}_{1 , 1} & … & {g}_{n} {y}_{1 , n} \\ {g}_{0} {y}_{2 , 0} & {g}_{1} {y}_{2 , 1} & … & {g}_{n} {y}_{2 , n} \\ ⋮ & ⋮ & ⋱ & ⋮ \\ {g}_{0} {y}_{m , 0} & {g}_{1} {y}_{m , 1} & … & {g}_{n} {y}_{m , n}\end{matrix}\end{matrix} ] \qquad ( 4 )$$

Presume a response from the object 220 when the object 220 is provided with all the specific manipulated variables Δf(t) after 0 to n samples. Assuming that response data in a time interval of exposure processing which is extracted from this response is represented by Y, Y is the sum of n responses, equation (5) given below holds:

$$\begin{matrix}Y = [ \begin{matrix}{Y}_{1} \\ {Y}_{2} \\ ⋮ \\ {Y}_{m}\end{matrix} ] = [ \begin{matrix}{g}_{0} {y}_{1 , 0} + {g}_{1} {y}_{1 , 1} + … + {g}_{n} {y}_{1 , n} \\ {g}_{0} {y}_{2 , 0} + {g}_{1} {y}_{2 , 1} + … + {g}_{n} {y}_{2 , n} \\ ⋮ \\ {g}_{0} {y}_{m , 0} + {g}_{1} {y}_{m , 1} + … + {g}_{n} {y}_{m , n}\end{matrix} ] \\ = [ \begin{matrix}{y}_{1 , 0} & {y}_{1 , 1} & … & {y}_{1 , n} \\ {y}_{2 , 0} & {y}_{2 , 1} & … & {y}_{2 , n} \\ ⋮ & ⋮ & ⋱ & ⋮ \\ {y}_{m , 0} & {y}_{m , 1} & … & {y}_{m , n}\end{matrix} ] [ \begin{matrix}{g}_{0} \\ {g}_{1} \\ ⋮ \\ {g}_{n}\end{matrix} ]\end{matrix} \qquad ( 5 )$$

In order to eliminate a control error (the control error data string eₑₓₚ) in a time interval of exposure processing by providing a feedforward manipulated variable to the object 220, the response data Y may be set to be equal to the control error data string eₑₓₚ. Accordingly, gains g₀ to gₙ of the feedforward controller 211 may be determined by using an inverse matrix or pseudo inverse matrix like that expressed by equation (6). Note that g₀ to gₙ are a parameter set indicating a characteristic of the feedforward controller 211 and may be called a feedforward table:

$$\begin{matrix}{e}_{exp} = Y \\ [ \begin{matrix}{e}_{1} \\ {e}_{2} \\ ⋮ \\ {e}_{m}\end{matrix} ] = [ \begin{matrix}{y}_{1 , 0} & {y}_{1 , 1} & … & {y}_{1 , n} \\ {y}_{2 , 0} & {y}_{2 , 1} & … & {y}_{2 , n} \\ ⋮ & ⋮ & ⋱ & ⋮ \\ {y}_{m , 0} & {y}_{m , 1} & … & {y}_{m , n}\end{matrix} ] [ \begin{matrix}{g}_{1} \\ {g}_{2} \\ ⋮ \\ {g}_{n}\end{matrix} ] \\ [ \begin{matrix}{g}_{1} \\ {g}_{2} \\ ⋮ \\ {g}_{n}\end{matrix} ] = {[ \begin{matrix}{y}_{1 , 0} & {y}_{1 , 1} & … & {y}_{1 , n} \\ {y}_{2 , 0} & {y}_{2 , 1} & … & {y}_{2 , n} \\ ⋮ & ⋮ & ⋱ & ⋮ \\ {y}_{m , 0} & {y}_{m , 1} & … & {y}_{m , n}\end{matrix} ]}^{- 1} [ \begin{matrix}{e}_{1} \\ {e}_{2} \\ ⋮ \\ {e}_{m}\end{matrix} ]\end{matrix} \qquad ( 6 )$$

A feedforward manipulated variable determined in accordance with this gain (that is, a feedforward manipulated variable gₙΔf(t+tₙ) obtained by multiplying the determined gain gₙ with a feedforward manipulated variable Δf(t+tₙ)) is provided to the object 220 at an operation time, as shown in FIG. 3C. Providing a feedforward manipulated variable to the object 220 makes it expected to reduce the control error in a time interval of exposure processing and improve the control accuracy as compared with a case where no feedforward manipulated variable is provided to the object 220.

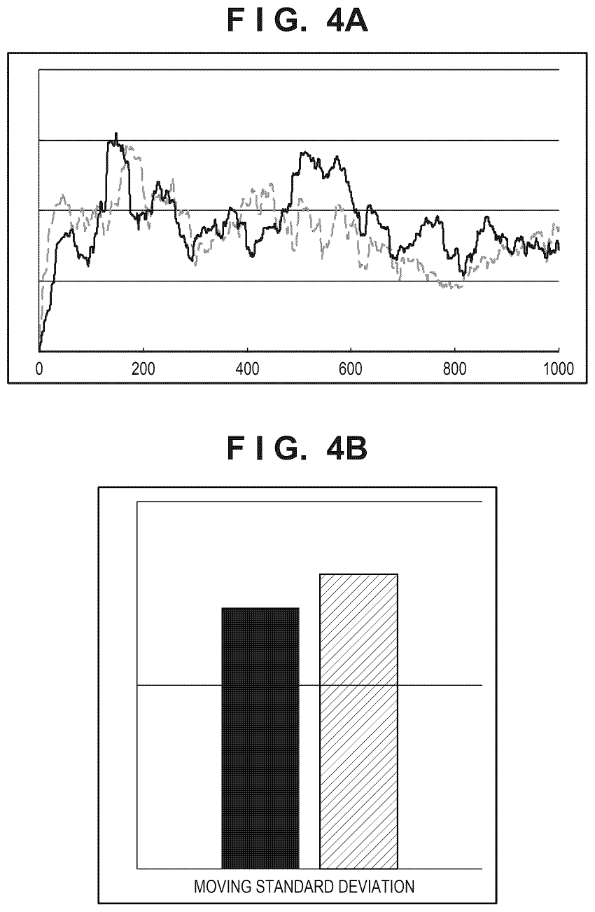

In this case, the control accuracy of the scanning exposure apparatus is sometimes evaluated by the maximum value of the moving standard deviation or moving average of control errors in a time interval of exposure processing, with the length of exposure light in the scanning direction being a window width. Since the exposure apparatus EXP is a scanning exposure apparatus that scans in the Y-axis direction, the control accuracy may be evaluated by the maximum value of the moving standard deviation of control errors in a time interval of exposure processing, with the length of the exposure light 108 in the Y-axis direction being a window width. In this case, as the maximum value of the moving standard deviation of control errors in a time interval of exposure processing decreases, the control accuracy may be evaluated as being high. FIGS. 4A and 4B each show an example of the moving standard deviation of control errors in the original plate stage mechanism 140 when the feedforward manipulated variable gₙΔf(t+tₙ) is provided to the original plate stage mechanism 140 of the exposure apparatus EXP. FIG. 4A is a graph indicating, on a time-series basis, the moving standard deviations of control errors in the original plate stage mechanism 140 from time 0 to time 1000 in a time interval of exposure processing. FIG. 4B is a graph indicating the maximum values of the moving standard deviations of control errors from time 0 to time 1000 in FIG. 4A.

Referring to FIG. 4A, the ordinate represents the moving standard deviation of control errors in the original plate stage mechanism 140, and the abscissa represents the time. Referring to FIG. 4A, the broken line indicates the moving standard deviation of control errors when the above feedforward manipulated variable is not provided to the original plate stage mechanism 140. Referring to FIG. 4A, the solid line indicates the moving standard deviation of control errors when the above feedforward manipulated variable is provided to the original plate stage mechanism 140. Referring to FIG. 4B, the ordinate represents the maximum value of the moving standard deviation of control errors in the original plate stage mechanism 140 from time 0 to time 1000. Referring to FIG. 4B, the left vertical bar indicates the maximum value of the moving standard deviation of control errors in a case where the above feedforward manipulated variable is not provided to the original plate stage mechanism 140. Referring to FIG. 4B, the right vertical bar indicates the maximum value of the moving standard deviation of control errors in a case where the above feedforward manipulated variable is provided to the original plate stage mechanism 140.

Referring to FIGS. 4A and 4B, in a case where a feedforward manipulated variable is provided to the original plate stage mechanism 140, the maximum value of the moving standard deviation of control errors in the mold driving unit 104 is larger than that in a case where no feedforward manipulated variable is provided to the original plate stage mechanism 140. That is, an expected improvement in control accuracy has not been achieved, but rather the opposite. The above phenomenon is caused because the reproducibility of a disturbance in the exposure apparatus EXP is low. That is, in a case where the reproducibility of the disturbance is low, the reproducibility of the control error data string eₑₓₚ used in the process of determining the feedforward manipulated variable gₙΔf(t+tₙ) is low, and hence the optimal feedforward manipulated variable gₙΔf(t+tₙ) is not determined.

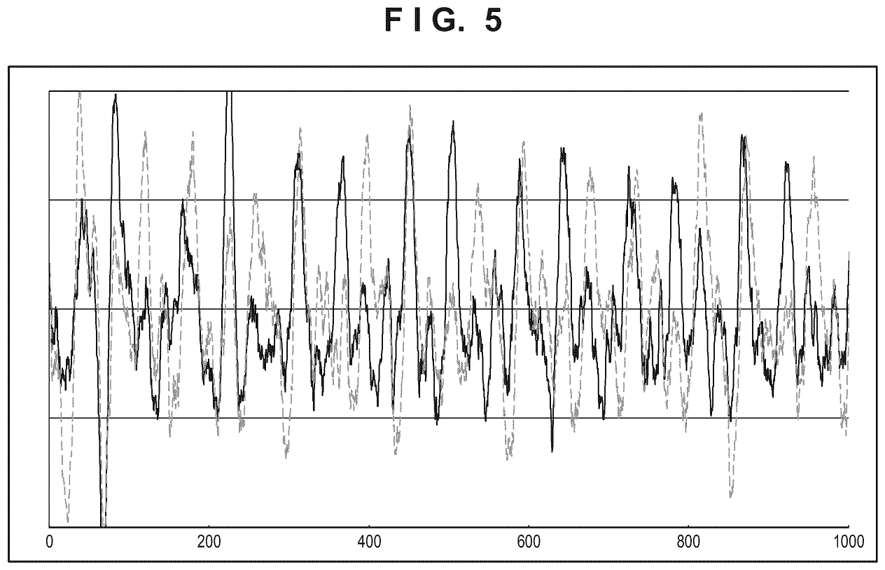

Consider the reproducibility of control errors in the original plate stage mechanism 140 in the exposure apparatus EXP with reference to FIG. 5. FIG. 5 is a graph indicating, on a time-series basis, the reproducibility of control errors in the original plate stage mechanism 140 from time 0 to time 1000 in a time interval of exposure processing. Referring to FIG. 5, the ordinate represents the control errors in the original plate stage mechanism 140, and the abscissa represents the time. In addition, referring to FIG. 5, the broken line indicates the control error, of the control errors in the original plate stage mechanism 140 acquired over a plurality of times, which is acquired at the first attempt, and the solid line indicates the control error in the original plate stage mechanism 140 which is acquired at the second attempt.

As is obvious from FIG. 5, there is a significant difference between the control error in the original plate stage mechanism 140 which is acquired at the first attempt and the control error in the original plate stage mechanism 140 which is acquired at the second attempt. A method of determining the feedforward manipulated variable gₙΔf(t+tₙ) is based on the premise that the reproducibility of a control error in the original plate stage mechanism 140 is high (the difference between the control errors acquired over a plurality of times is negligibly small). Accordingly, as exemplarily shown in FIG. 5, in a situation in which the reproducibility of control errors is low, no control accuracy improving effect appears. In order to obtain a control accuracy improving effect even in the situation exemplarily shown in FIG. 5, what is preferred or used is a method of determining the feedforward manipulated variable gₙΔf(t+tₙ) in consideration of a disturbance environment with low reproducibility. A method of solving the above issues will be described below.

Consider a control error e(t) in the object 220 under a disturbance environment with low reproducibility. Assuming that a control error e₁ at time 1 may be separated into a component e_{1_steady} with high reproducibility and a component e₁′ with low reproducibility, the control error e₁ is expressed as equation (7):

$${e}_{1} = {e}_{{1}_{steady}} + {e}_{1}^{′} \qquad ( 7 )$$

Likewise, assuming that a control error at time 2, a control error at time 3, . . . , a control error at time m are respectively represented by e₂, e₃, . . . , eₘ, the control error data string eₑₓₚ given by equation (1) is expressed as equation (8):

$${e}_{ex p} = {[ \begin{matrix}{e}_{1 \_ steady} + {e}_{1}^{′} & {e}_{2 \_ steady} + {e}_{2}^{′} & … & {e}_{m \_ steady} + {e}_{m}^{′}\end{matrix} ]}^{T} \qquad ( 8 )$$

Consider a case where the control error data string eₑₓₚ is acquired over a plurality of times. Assume that a control error data string acquired at the first attempt, a control error acquired at the second attempt, . . . , a control error data string acquired at the kth attempt are respectively represented by eₑₓₚ₁, eₑₓₚ₂, . . . , eₑₓₚₖ. Assuming that the average value of control error data strings acquired at the first attempt to the kth attempt is represented by e_{exp_ave}, the average e_{exp_ave} is expressed as equation (9) given below:

$$\begin{matrix}{e}_{ex {p}_{ave}} = [ \begin{matrix}{e}_{{1}_{ave}} \\ {e}_{{2}_{ave}} \\ … \\ {e}_{{m}_{ave}}\end{matrix} ] \\ = [ \begin{matrix}\frac{{e}_{1 , 1} + {e}_{2 , 1} + … + {e}_{k , 1}}{k} \\ \frac{{e}_{1 , 2} + {e}_{2 , 2} + … + {e}_{k , 2}}{k} \\ … \\ \frac{{e}_{1 , m} + {e}_{2 , m} + … + {e}_{k , m}}{k}\end{matrix} ] \\ = [ \begin{matrix}{e}_{1 \_ steady} \\ {e}_{2 \_ steady} \\ … \\ {e}_{m \_ steady}\end{matrix} ]\end{matrix} \qquad ( 9 )$$

In this case, assume that a disturbance component with low reproducibility is completely random, and if k is sufficiently large, the total sum of the values of the control error data strings acquired at the first attempt to the kth attempt converges to 0. Under this assumption, the average value e_{exp_ave} of the control error data strings is expressed as equation (10):

$${e}_{ex p\_ave} = {[ \begin{matrix}{e}_{1 \_ steady} & {e}_{2 \_ steady} & … & {e}_{m \_ steady}\end{matrix} ]}^{T} \qquad ( 10 )$$

As is obvious from equation (10), obtaining the average value e_{exp_ave} of the control error data strings acquired over a plurality of times may eliminate disturbance components with low reproducibility included in the control error data string eₑₓₚ. The above example uses the method of obtaining an average value, but a method of obtaining a median value may be used. Assuming that if k is sufficiently large, the median value converges to 0, equation (10) may be obtained in a similar manner. Note that a method of obtaining a representative value instead of an average value or median value may be used. A representative value is a value indicating the central trend of a group.

As described above, it is useful that the feedforward manipulated variable gₙΔf(t+tₙ) is determined by extracting only a disturbance component with high reproducibility from the control error data string eₑₓₚ by obtaining a representative value such as an average value or median value of a control error data string. This method may improve the control accuracy by feedforward control even in an environment including a disturbance with low reproducibility. Some embodiments will be described below.

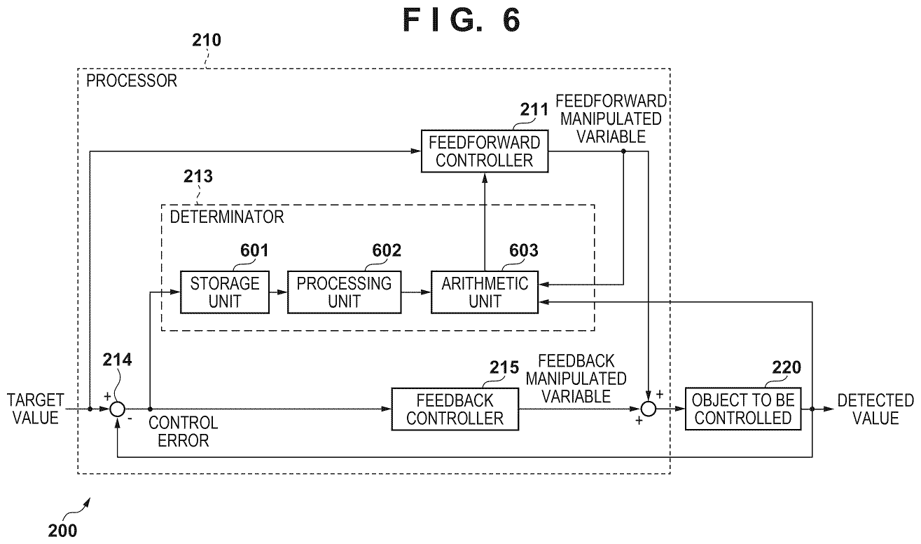

FIG. 6 shows at least one embodiment example of an arrangement of a control apparatus 200 according to one or more aspects of the present disclosure. Matters or embodiments that do not refer to the control apparatus 200 according to at least one embodiment example may comply with the description about one or more arrangements of one or more additional, one or more further, or one or more another embodiment examples of the control apparatuses 200 according to one or more aspects of the present disclosure. The processor 210 may include, for example, the feedforward controller 211 that generates a feedforward manipulated variable in accordance with a target value and provides the feedforward manipulated variable to the object 220. In addition, the processor 210 may include the subtractor 214 that calculates a control error in the object 220 and a feedback controller 215 that generates a feedback manipulated variable corresponding to a control error and provides the feedback manipulated variable to the object 220. The processor 210 may also include an adder 216 that generates the sum of a feedforward manipulated variable and a feedback manipulated variable as a manipulated variable for controlling the object 220. The processor 210 may further include the determinator 213 that determines the gain of the feedforward controller 211.

The determinator 213 may generate a representative value data string constituted by the representative values of control errors at the respective times based on a plurality of control error data strings acquired over a plurality of times and determine the gain of the feedforward controller 211 based on the representative value data string and the response data string. The determinator 213 may include, for example, a storage unit 601, a processing unit 602, and an arithmetic unit 603. The processor 210 may acquire a control error string indicating a change in control error in the object 220 over a plurality of times. The storage unit 601 may accumulate a plurality of control error data strings acquired over a plurality of times. The processing unit 602 generates a representative value data string constituted by the representative values of control errors at the respective times based on a plurality of control error data strings accumulated in the storage unit 601 and provides the representative value data string to the arithmetic unit 603. The arithmetic unit 603 may determine the gain of the feedforward controller 211 based on the representative value data string provided from the processing unit 602 and the response data string provided from the object 220. In this case, as described above, the response data string is the detected value data string output from the object 220 while a specific manipulated variable for specifying a characteristic of the object 220 is provided to the object 220.

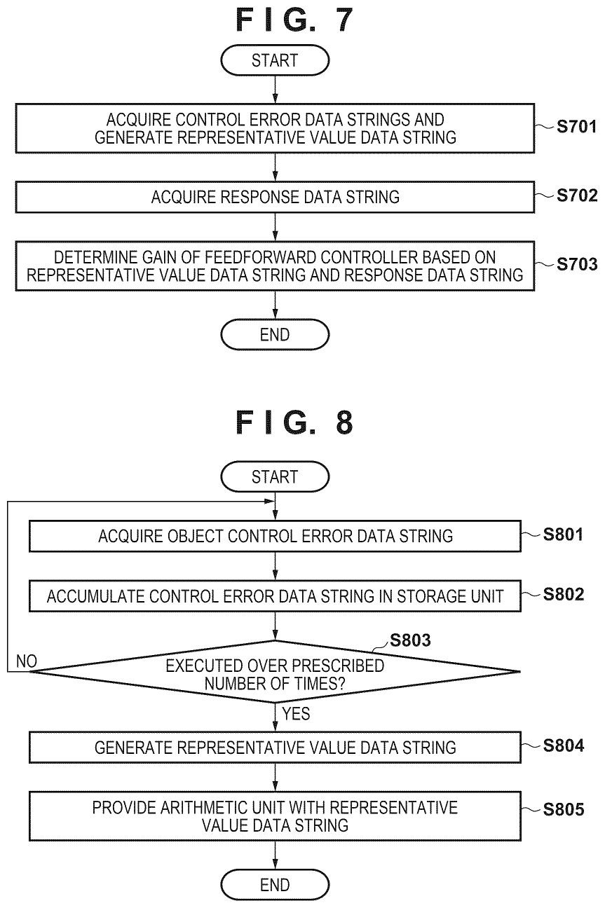

FIG. 7 is a flowchart exemplarily showing a procedure in at least one embodiment of a method of determining the gain of the feedforward controller 211. The processor 210 executes this procedure. In step S701, the processor 210 acquires a plurality of control error data strings and accumulates them in the storage unit 601, and the processing unit 602 generates a representative value data string from the plurality of control error data strings and provides the representative value data string to the arithmetic unit 603. In step S702, the processor 210 acquires a response data string. In step S703, the processor 210 (the arithmetic unit 603) determines the gain of the feedforward controller 211 based on the representative value data string and the response data string. Note that step S702 may be executed before step S701.

FIG. 8 is a flowchart exemplarily showing at least one embodiment of details of an acquisition step (step S701) for the representative value data string of control errors according to one or more aspects of the present disclosure. In step S801, the processor 210 acquires a control error data string indicating a change in control error (output from the subtractor 214) in the object 220 while a predetermined target value is provided to the subtractor 214. In step S802, the processor 210 accumulates the control error data string acquired in step S801 in the storage unit 601. In step S803, the processor 210 determines whether the sequence constituted by steps S801 and S802 has been executed over a prescribed number of times. In a case where the processor 210 determines that the sequence has been executed over the prescribed number of times, the process advances to step S804. Otherwise, the processor 210 executes the sequence constituted by steps S801 and S802.

In step S804, the processor 210 generates the representative value data string constituted by the representative values of control errors in the object 220 at the respective times based on a plurality of control error data strings acquired over a plurality of times and accumulated in the storage unit 601 by the processing unit 602. In step S805, the processor 210 provides the arithmetic unit 603 with the representative value data string generated in step S804.

The operation in step S701 shown in FIG. 8 will be described more specifically below. First of all, the processor 210 acquires, for example, a control error data string in a time interval of exposure processing according to (1) and repeats the operation over a prescribed number of times. The processor 210 accumulates, for example, the control error data string acquired at the first attempt, the control error data string acquired at the second attempt, . . . , the control error data string acquired at the kth attempt in the storage unit 601 as eₑₓₚ₁, eₑₓₚ₂, . . . , eₑₓₚₖ. The processing unit 602 generates the representative value data string constituted by the representative values of control errors at the respective times in the object 220 based on a plurality of control error data strings accumulated in the storage unit 601. The processing unit 602 may generate a representative value data string based on all the control error data strings accumulated in the storage unit 601 or may generate a representative value data string based on at least two control error data strings selected from all the control error data strings accumulated in the storage unit 601. The following is a description of an example of generating a representative value data string based on all the control error data strings accumulated in the storage unit 601. An example of using an average value as a representative value will be described below. Generating a representative value data string based on a plurality of control error data strings makes it possible to eliminate a disturbance component with low reproducibility that may be included in a plurality of control error data strings.

Assuming that the number of control error data strings to be used is k, the representative value data string e_{exp_ave} obtained from k control error data strings according to equation (10) is expressed as equation (11) given below:

$$\begin{matrix}{e}_{ex {p}_{ave}} = [ \begin{matrix}{e}_{{1}_{ave}} \\ {e}_{{2}_{ave}} \\ … \\ {e}_{{m}_{ave}}\end{matrix} ] \\ = [ \begin{matrix}\frac{{e}_{1 , 1} + {e}_{2 , 1} + … + {e}_{k , 1}}{k} \\ \frac{{e}_{1 , 2} + {e}_{2 , 2} + … + {e}_{k , 2}}{k} \\ … \\ \frac{{e}_{1 , m} + {e}_{2 , m} + … + {e}_{k , m}}{k}\end{matrix} ] \\ = [ \begin{matrix}{e}_{1 \_ steady} \\ {e}_{2 \_ steady} \\ … \\ {e}_{m \_ steady}\end{matrix} ]\end{matrix} \qquad ( 11 )$$

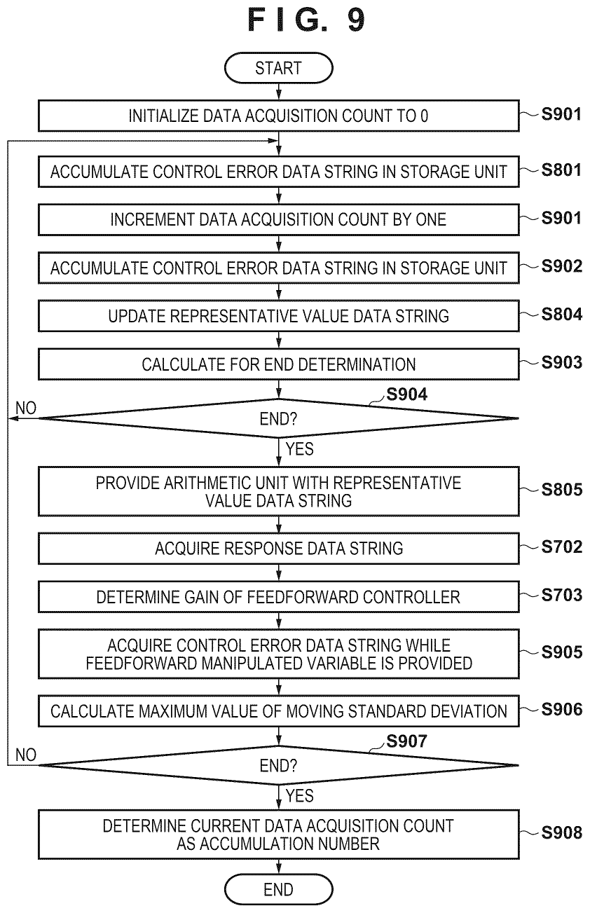

The accumulation number (prescribed count) of control error data strings may be determined by the following method. FIG. 9 is a flowchart exemplarily showing at least one embodiment of details of the processing of determining the accumulation number (prescribed count) of control error data strings according to one or more aspects of the present disclosure. Step S901 is executed before step S801, and step S902 is executed between step S801 and step S802. Steps S903 and S904 are executed between step S804 and step S805, and steps S905 and S908 are executed after step S703. In step S901, the processor 210 initializes the data acquisition count to 0. In step S902, the processor 210 increments the data acquisition count by one. In step S903, the processor 210 performs calculation for end determination. More specifically, the processor 210 calculates the total sum of the absolute values of the differences between control errors of the latest two control error data strings output from the processing unit 602 at the respective times. In step S904, the processor 210 determines whether the total sum calculated in step S903 is less than a threshold. The threshold may be determined based on, for example, the magnitude of the amplitude of a control error data string or based on experiences or according to another method. In a case where the determination result is true, the processor 210 advances the process to step S805. In a case where the determination result is false, the processor 210 returns the process to step S801.

In step S905, the processor 210 acquires a control error data string of the object 220 while a feedforward manipulated variable is provided to the object 220. In step S906, the processor 210 calculates the maximum value of the moving standard deviation of the control error data string acquired in step S905. This example is described assuming that the maximum value of the moving standard deviation of a control error data string is obtained. However, what is obtained need not always be a moving standard deviation and may be, for example, a moving average, with the length of the exposure light 108 in the Y-axis direction being a window width. In step S907, the processor 210 determines whether the result calculated in step S906 is less than a threshold. The threshold may be determined based on, for example, required, preferred, or used control accuracy or experiences or according to another method. In a case where the determination result is true, the processor 210 advances the process to step S908. In a case where the determination result is false, the processor 210 returns the process to step S801. In step S908, the processor 210 determines the current data acquisition count as an accumulation number. As described above, the accumulation number of control error data strings may be determined in accordance with a sequence.

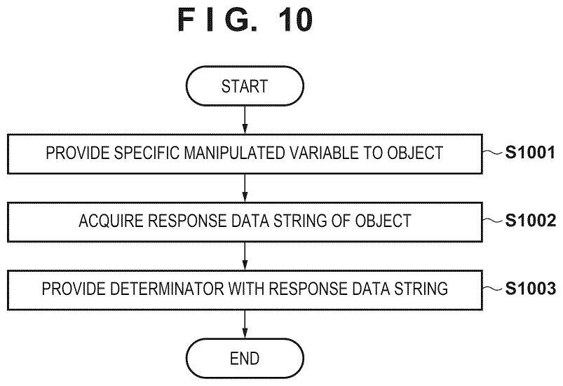

FIG. 10 is a flowchart exemplarily showing at least one embodiment of details of a step (step S702) of acquiring a response data string according to one or more aspects of the present disclosure. In step S1001, the processor 210 provides a specific manipulated variable to the object 220. In step S1002, the processor 210 acquires the first response data string output from the object 220 in response to the provided specific manipulated variable. In step S1003, the processor 210 provides the first response data string acquired in step S1002 to the arithmetic unit 603.

The above procedure prepares the average value e_{exp_ave} of the control error data string obtained according to equation (11) and the first response data string y₀ expressed by equation (2). The arithmetic unit 603 determines the gain gₙ of the feedforward controller 211 based on these values according to equation (6). That is, the arithmetic unit 603 determines the gain gₙ of the feedforward controller 211 by using an inverse matrix or pseudo inverse matrix like that expressed by equation (12):

$$\begin{matrix}{e}_{exp\_ave} = Y \\ [ \begin{matrix}{e}_{1 \_ steady} \\ {e}_{2 \_ steady} \\ … \\ {e}_{m \_ steady}\end{matrix} ] = [ \begin{matrix}{y}_{1 , 0} & {y}_{1 , 1} & … & {y}_{1 , n} \\ {y}_{2 , 0} & {y}_{2 , 1} & … & {y}_{2 , n} \\ ⋮ & ⋮ & ⋱ & ⋮ \\ {y}_{m , 0} & {y}_{m , 1} & … & {y}_{m , n}\end{matrix} ] [ \begin{matrix}{g}_{1} \\ {g}_{2} \\ ⋮ \\ {g}_{n}\end{matrix} ] \\ [ \begin{matrix}{g}_{1} \\ {g}_{2} \\ ⋮ \\ {g}_{n}\end{matrix} ] = {[ \begin{matrix}{y}_{1 , 0} & {y}_{1 , 1} & … & {y}_{1 , n} \\ {y}_{2 , 0} & {y}_{2 , 1} & … & {y}_{2 , n} \\ ⋮ & ⋮ & ⋱ & ⋮ \\ {y}_{m , 0} & {y}_{m , 1} & … & {y}_{m , n}\end{matrix} ]}^{- 1} [ \begin{matrix}{e}_{1 \_ steady} \\ {e}_{2 \_ steady} \\ … \\ {e}_{m \_ steady}\end{matrix} ]\end{matrix} \qquad ( 12 )$$

The object 220 may be provided with the feedforward manipulated variable determined according to the gain determined in this manner (that is, the feedforward manipulated variable gₙΔf(t+tₙ) obtained by multiplying the feedforward manipulated variable Δf(t+tₙ) with the determined gain gₙ) at an operation time. This reduces the control error in a time interval of exposure processing and improves the control accuracy as compared with a case where no feedforward manipulated variable is provided to the object 220.

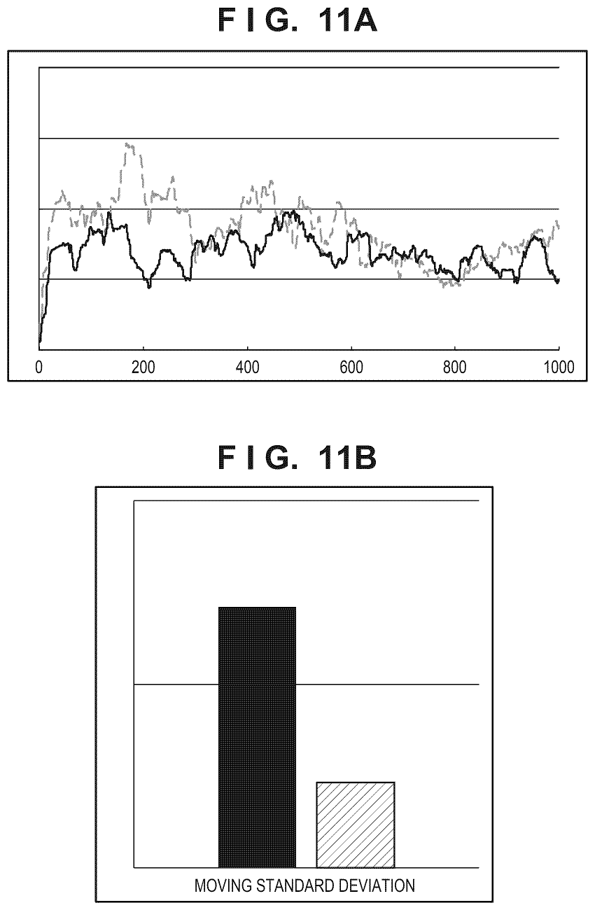

FIGS. 11A and 11B exemplarily show the moving standard deviations of control errors in one or more embodiments of the original plate stage mechanism 140 in a case where the feedforward manipulated variables gₙΔf(t+tₙ) are provided to the original plate stage mechanism 140 of the exposure apparatus EXP. FIG. 11A is a graph indicating, on a time-series basis, the moving standard deviations of control errors in the original plate stage mechanism 140 from time 0 to time 1000 in a time interval of exposure processing. FIG. 11B is a graph indicating the maximum values of the moving standard deviations of control errors from time 0 to time 1000 in FIG. 11A. Referring to FIG. 11A, the ordinate represents the moving standard deviation of control errors in one or more embodiments of the original plate stage mechanism 140, and the abscissa represents the time. Referring to FIG. 11A, the broken line indicates the moving standard deviation of control errors in a case where the feedforward manipulated variable determined by the one or more embodiments is not provided to the original plate stage mechanism 140. Referring to FIG. 11A, the solid line indicates the moving standard deviation of control errors in a case where the feedforward manipulated variable determined by one or more embodiments is provided to the original plate stage mechanism 140. Referring to FIG. 11B, the ordinate represents the maximum value of the moving standard deviation of control errors in the original plate stage mechanism 140 from time 0 to time 1000. Referring to FIG. 11B, the left vertical bar indicates the maximum value of the moving standard deviation of control errors in a case where the feedforward manipulated variable determined by one or more embodiments is not provided to the original plate stage mechanism 140. Referring to FIG. 11B, the right vertical bar indicates the maximum value of the moving standard deviation of control errors in a case where the feedforward manipulated variable determined by one or more embodiments is provided to the original plate stage mechanism 140. Referring to FIGS. 11A and 11B, in a case where the feedforward manipulated variable determined by one or more embodiments is provided to the original plate stage mechanism 140, the maximum value of the moving standard deviation of control errors in the original plate stage mechanism 140 is smaller than otherwise.

As described above, according to one or more embodiments of the present disclosure, it is possible to improve the control accuracy by feedforward control even under an environment including a disturbance with low reproducibility.

A control apparatus 200 according to one or more additional embodiments of the present disclosure will be described below. Matters or embodiments that do not refer to the control apparatus 200 according to the one or more additional embodiments may comply with the description about the control apparatuses 200 according to the one or more embodiments discussed above or herein. In one or more additional embodiments, a processor 210 generates the first representative value data string constituted by representative values of control errors in an object 220 at the respective times based on a plurality of control error data strings acquired over a plurality of times. In addition, the processor 210 determines the second representative value data string constituted by the representative values of the response characteristic of the object 220 at the respective times based on a plurality of response data strings acquired over a plurality of times. The processor 210 then determines the gain (feedforward table) of a feedforward controller 211 based on the first representative value data string generated based on the plurality of control error data strings and the second representative value data string generated from the plurality of response data strings.

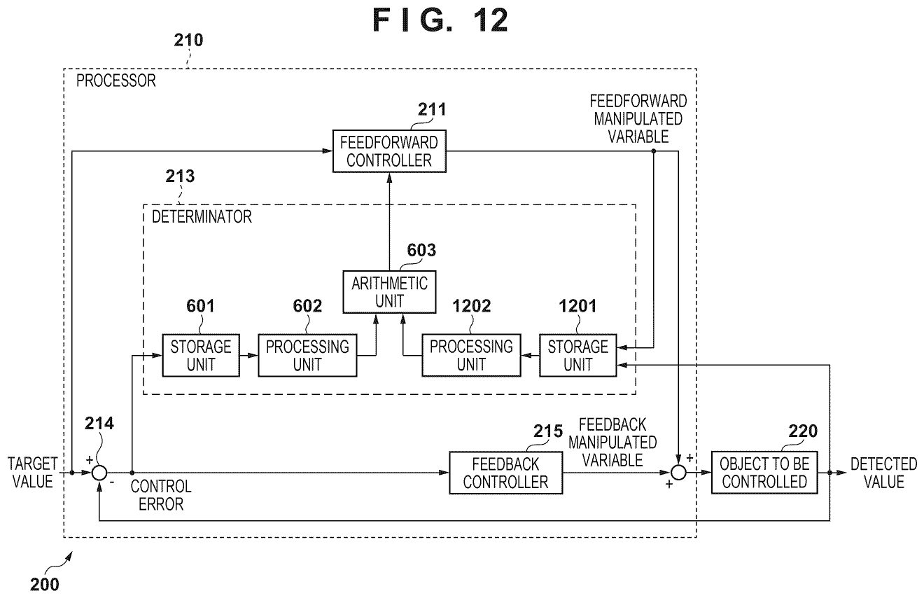

FIG. 12 shows an example of the arrangement of the control apparatus 200 according to the one or more additional embodiments of the present disclosure. In the processor 210 of the control apparatus 200 according to the one or more additional embodiments, the arrangement of a determinator 213 is different from that of the determinator 213 according to at least one of the one or more embodiments discussed above. In the control apparatus 200 according to the one or more additional embodiments, the determinator 213 may include a first storage unit 601, a first processing unit 602, a second storage unit 1201, a second processing unit 1202, and an arithmetic unit 603. The processor 210 may acquire a control error data string indicating a change in control error in the object 220 over a plurality of times. The first storage unit 601 may accumulate a plurality of control error data strings acquired over a plurality of times. The first processing unit 602 generates a representative value data string constituted by the representative values of control errors at the respective times based on a plurality of control error data strings accumulated in the first storage unit 601 and provides the representative value data string to the arithmetic unit 603.

The processor 210 acquires the response data string output from the object 220 over a plurality of times while a specific manipulated variable for specifying a characteristic of the object 220 is provided to the object 220. The second storage unit 1201 accumulates the plurality of response data strings acquired over a plurality of times. The second processing unit 1202 generates the second representative value data string constituted by the representative values of the response characteristic of the object 220 at the respective times based on the plurality of response data strings acquired over a plurality of times and provides the second representative value data string to the arithmetic unit 603. The arithmetic unit 603 may determine the gain (feedforward table) of the feedforward controller 211 based on the first representative value data string provided from the first processing unit 602 and the second representative value data string provided from the object 220.

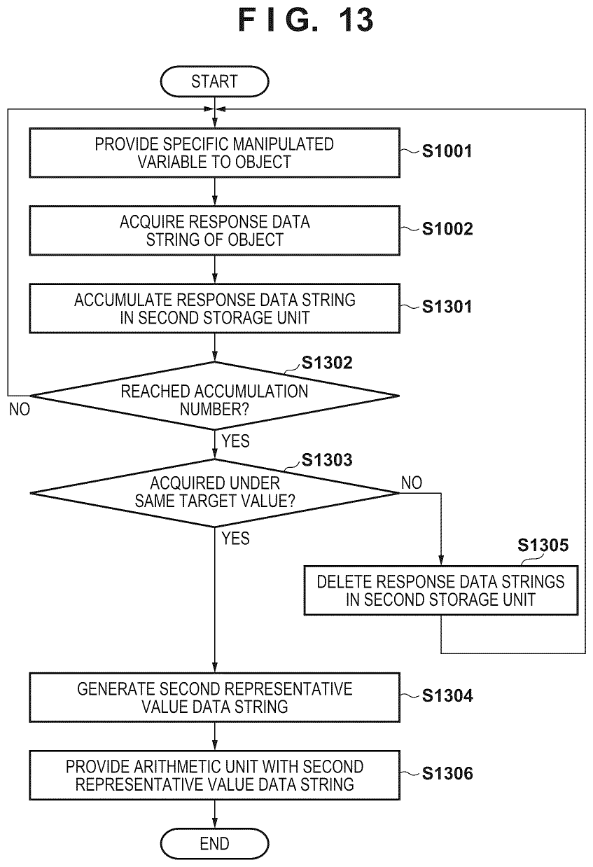

FIG. 13 is a flowchart exemplarily showing the details of an acquisition step (step S702) for a representative value data string of a response characteristic in the one or more additional embodiments of the present disclosure. In the one or more additional embodiments, steps S1301 to S1306 are executed after step S1002. In step S1301, the processor 210 accumulates the response data string acquired in step S1002 in the second storage unit 1201. In step S1302, the processor 210 determines whether the sequence constituted by steps S1001, S1002, and S1301 has been executed over a preset accumulation number. Upon determining that the sequence has been executed over the accumulation number, the processor 210 advances the process to step S1303. Otherwise, the processor 210 executes the sequence constituted by steps S1001, S1002, and S1301. The accumulation number may be determined by the accumulation number determination flowchart obtained by applying the control error data string accumulation number determination flowchart shown in FIG. 9 to the response data string accumulation number determination flowchart or the memory capacity allocated to the first storage unit 601. Alternatively, the accumulation number may be determined according to experiences or another method.

In step S1303, the processor 210 determines whether all the response data strings stored in the second storage unit 1201 have been acquired by controlling the object 220 under the same target value (the same position in this case). If the determination result is true, the processor 210 advances the process to step S1304. If the determination result is false, the processor 210 executes step S1305 and then returns the process to step S1001. In step S1304, the processor 210 causes the second processing unit 1202 to generate the second representative value data string constituted by the representative values of the response characteristic of the object 220 at the respective times based on the plurality of response data strings acquired over a plurality of times and accumulated in the second storage unit 1201. The second processing unit 1202 may generate the second representative value data string based on all the response data strings accumulated in the second storage unit 1201. Alternatively, the second processing unit 1202 may generate the second representative value data string based on at least two response data strings selected from all the response data strings accumulated in the second storage unit 1201.

In step S1305, the processor 210 deletes all the response data strings accumulated in the second storage unit 1201. The following will describe an example in which all the response data strings are deleted. However, all the response data strings need not always be deleted, and response data strings acquired with the same target value (the same position) may be left, and response data strings acquired with another target value may be deleted. In step S1306, the processor 210 provides the arithmetic unit 603 with the second representative value data string generated in step S1304.

In the one or more additional embodiments, the processor 210 determines the gain of the feedforward controller 211 based on the first representative value data string generated from a plurality of control error data strings acquired over a plurality of times and the second representative value data string generated from a plurality of response data strings. It is, therefore, possible to improve the control accuracy by feedforward control even under an environment including a disturbance with low reproducibility.

A control apparatus 200 according to one or more further embodiments of the present disclosure will be described below. Matters or embodiments that do not refer to the control apparatus 200 according to the one or more further embodiments may comply with the description about the control apparatuses 200 according to the one or more embodiments or the one or more additional embodiments discussed above or herein. In the one or more embodiments or the one or more additional embodiments, the processor 210 accumulates control error data strings in the storage unit 601 without determining whether a control error data string from the object 220 includes a disturbance component with low reproducibility. However, under a disturbance environment with low reproducibility, a control error data string includes no disturbance component with low reproducibility to be eliminated. That is, since each control error in each of control error data strings acquired over a plurality of times is equal to the representative value of the control errors, there is no need to acquire control error data strings over a plurality of times and generate a representative value data string based on the acquired data strings.

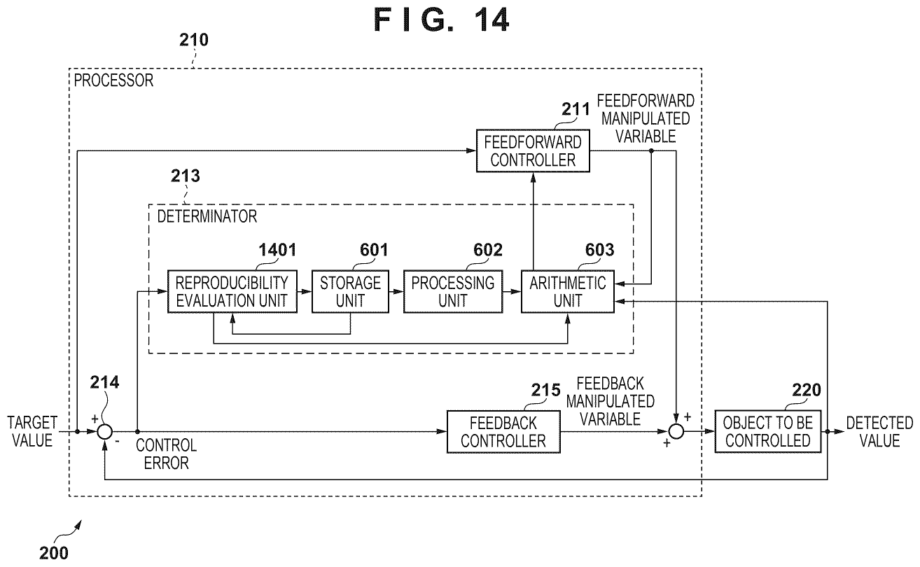

FIG. 14 shows at least one further embodiment example of an arrangement of the control apparatus 200 according to one or more aspects of the present disclosure. In the one or more further embodiments, a determinator 213 includes a reproducibility evaluation unit 1401. The reproducibility evaluation unit 1401 evaluates the reproducibility of a control error data string by comparing the control error data string accumulated in the storage unit 601 with the newly acquired control error data string of the object 220. Upon evaluating that the reproducibility satisfies a criterion, the reproducibility evaluation unit 1401 provides the newly acquired control error data string to an arithmetic unit 603. Upon evaluating that the reproducibility does not satisfy the criterion, the reproducibility evaluation unit 1401 accumulates control error data strings in the storage unit 601 until the same number of control error data strings as a predetermined accumulation number are accumulated in the storage unit 601. A processing unit 602 generates a representative value data string based on a plurality of control error data strings accumulated in the storage unit 601 and provides the representative value data string to the arithmetic unit 603.

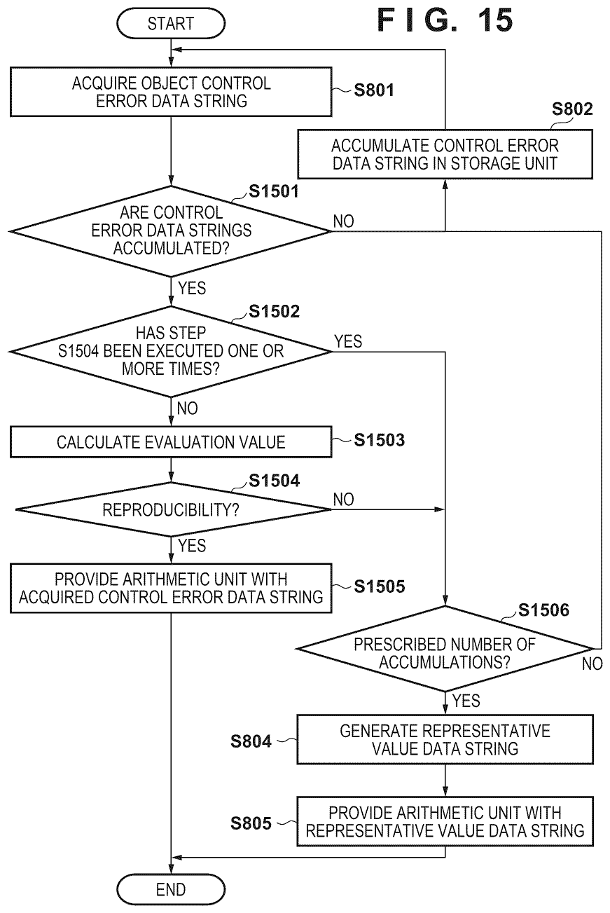

FIG. 15 is a flowchart exemplarily showing at least one embodiment of details of a step of acquiring the representative value data string of control errors that may be used in one or more further embodiments according to one or more aspects of the present disclosure. The processor 210 executes step S1501 after step S801. In step S1501, the processor 210 determines whether one or more control error data strings are accumulated in the storage unit 601. In a case where the determination result is true, the processor 210 advances the process to step S1502. In a case where the determination result is false, the processor 210 executes step S802 and then returns the process to step S801. The processor 210 determines in step S1502 whether step S1504 has been executed one or more times. In a case where the determination result is true, the processor 210 advances the process to step S1506. In a case where the determination result is false, the processor 210 advances the process to step S1503. In step S1503, the processor 210 calculates, as an evaluation value, the total sum of the absolute values of the differences between the control errors of the control error data strings accumulated in the storage unit 601 and the control error data strings newly acquired in step S801 at the respective times. In step S1504, the processor 210 determines whether the total sum calculated as the evaluation value in step S1503 is less than a predetermined threshold, that is, whether the reproducibility of the control error data string satisfies a criterion. The threshold may be determined by, for example, the magnitude of the amplitude of the control error data string or experiences or according to another method. In a case where the determination result is true, the processor 210 advances the process to step S1505. In a case where the determination result is false, the processor 210 advances the process to step S1506. In step S1505, the processor 210 provides the control error data string acquired in step S801 to the arithmetic unit 603. In step S1506, the processor 210 determines whether the accumulation count of control error data strings in the storage unit 601 (that is, the number of accumulated control error data strings) satisfies a predetermined accumulation count. In a case where the determination result is true, the processor 210 advances the process to step S804. In a case where the determination result is false, the processor 210 executes step S802 and then returns the process to step S801.

As described above, in one or more further embodiments, the control apparatus 200 determines whether the current environment is a disturbance environment with low reproducibility. Upon determining that the current environment is a disturbance environment with low reproducibility, the control apparatus 200 uses the representative value data string generated based on a plurality of control error data strings to determine the gain of a feedforward controller 211. In contrast to this, upon determining that the current environment is a disturbance environment with high reproducibility, the control apparatus 200 uses the latest control error data string to determine the gain of the feedforward controller 211. According to the one or more further embodiments, therefore, it is possible to improve the control accuracy by feedforward control regardless of whether the current environment includes a disturbance with low reproducibility.

A control apparatus 200 according to one or more another embodiments will be described below. Matters or embodiments that do not refer to the control apparatus 200 according to the one or more another embodiments may comply with the description about the control apparatuses 200 according to any one of the other one or more embodiments, one or more additional embodiments, and/or one or more further embodiments discussed above or herein. In the one or more embodiments, a representative value data string is generated by using a predetermined accumulation number of control data strings. However, under an environment including a disturbance with low reproducibility, the accumulation number of control error data strings preferred or used to eliminate a disturbance component with low reproducibility from a control error data string may change.

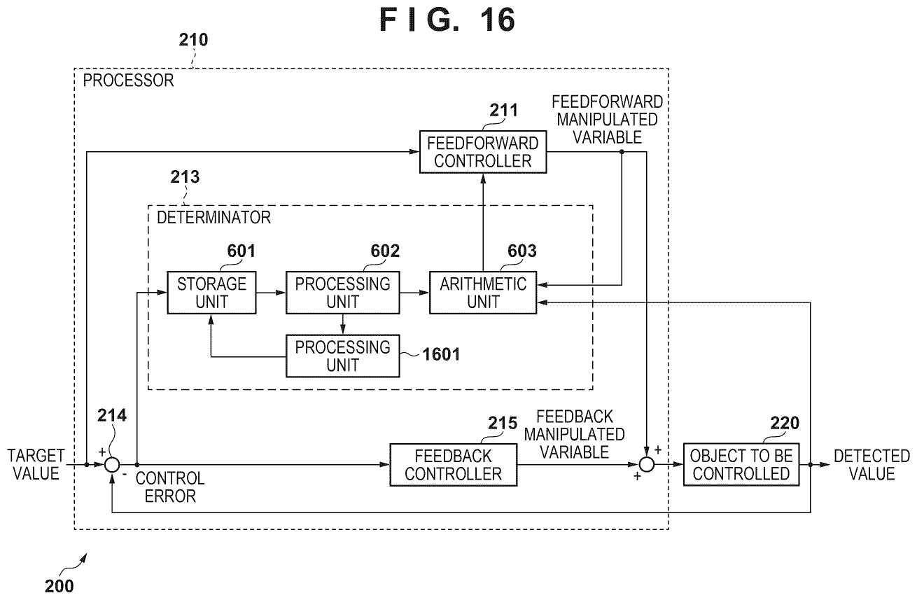

FIG. 16 shows at least one other (or another) embodiment example of an arrangement of a control apparatus 200 that may be used according to one or more aspects of the present disclosure. In the at least one other (or another) embodiment, a determinator 213 includes a count determination unit 1601. The count determination unit 1601 counts a pass count that the total sum of the absolute values of the differences between the representative values of the latest two representative value data strings output from a processing unit 602 at the respective times becomes less than a predetermined threshold and accumulates control error data strings in a storage unit 601 until the pass count becomes a prescribed count determined in advance.

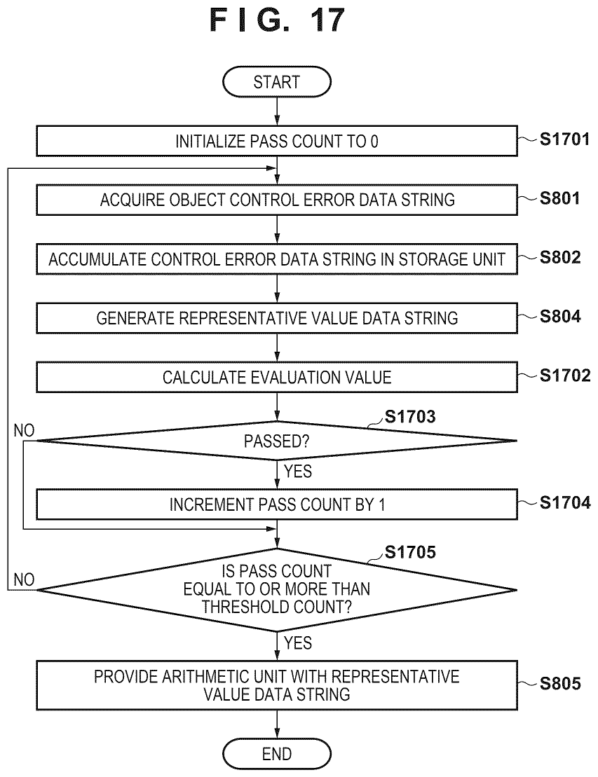

FIG. 17 is a flowchart exemplarily showing the details of a step of acquiring the representative value data string of control errors in the at least one another (or another) embodiment. A processor 210 executes step S1701 before step S801. The processor 210 executes steps S1702 to S1705 between step S804 and step S805. In step S1701, the processor 210 initializes the pass count held by the count determination unit 1601 to 0. In step S1702, the count determination unit 1601 calculates, as an evaluation value, the total sum of the absolute values of the differences between the representative values of the latest two representative value data strings generated by the processing unit 602 at the respective times. In step S1703, the count determination unit 1601 determines whether the evaluation value calculated in step S1702 is less than the predetermined threshold, that is, whether the evaluation value meets a pass criterion. The threshold may be determined, for example, based on the magnitude of the amplitude of a control error data string or experiences or according to another method. In a case where the determination result is true, the processor 210 advances the process to step S1704. In a case where the determination result is false, the processor 210 advances the process to step S1705. In step S1704, the processor 210 increments the pass count held by the count determination unit 1601 by one. In step S1705, the processor 210 determines whether the pass count held by the count determination unit 1601 is equal to or more than a predetermined count (threshold count). The threshold count may be determined based on, for example, experiences. In a case where the determination result is true, the processor 210 advances the process to step S805. In a case where the determination result is false, the processor 210 returns the process to step S801.

As described above, under an environment including a disturbance with low reproducibility, the at least one other (or another) embodiment is configured to dynamically determine the accumulation number of control error data strings preferred or that may be used to eliminate a disturbance component with low reproducibility which is included in a control error data string used to determine the gain of a feedforward controller 211. This makes it possible to determine the gain of the feedforward controller 211 based on the representative value data string corresponding to the reproducibility of a disturbance. Accordingly, even under an environment including a disturbance with low reproducibility, an object 220 may be controlled based on a necessary and sufficient number of control error data strings.

In a case where the control apparatus 200 is applied to an exposure apparatus EXP, the object 220 may be an original plate stage mechanism 140 or a substrate stage mechanism 150. Alternatively, the object 220 may be another constituent element to be subjected to feedforward control. The original plate stage mechanism 140 and/or the substrate stage mechanism 150 is an example of a stage mechanism for aligning an original plate 103 with a substrate 106.

An article manufacturing method of manufacturing an article by using a lithography apparatus such as the exposure apparatus EXP will be described below. The article manufacturing method may include a transfer step of transferring the pattern of an original plate onto a substrate by using the lithography apparatus and a processing step of obtaining an article by processing the substrate having undergone the transfer step. An article may be, for example, a microdevice such as a semiconductor device, a display, or an element such as a MEMS having a microstructure. The lithography apparatus is not limited to an exposure apparatus and may be, for example, an imprint apparatus. The processing step may include, for example, developing, etching, oxidation, deposition, vapor deposition, doping, planarization, resist separation, dicing, bonding, and packaging.

### One or More Other Embodiments

Embodiment(s) of the present disclosure may also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU), etc.) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims priority to and the benefit of Japanese Patent Application No. 2024-180338, filed Oct. 15, 2024, which is hereby incorporated by reference herein in its entirety.

What is claimed is:

1. A control apparatus that operates to control an object based on a feedforward manipulated variable generated by a feedforward controller, the control apparatus comprising:
a determinator that operates to: (i) determine a gain of the feedforward controller based on a control error data string indicating a change in a control error of the object and a response data string indicating a response characteristic of the object in a case where a specific manipulated variable is provided to the object; and (ii) generate a representative value data string constituted by representative values of control errors of the object at respective times based on a plurality of control error data strings acquired over a plurality of times and determine the gain based on the representative value data string and the response data string.

2. The control apparatus according to claim 1, further comprising:
a feedback controller that operates to generate a feedback manipulated variable based on the control errors of the object; and
an adder that operates to generate, as a manipulated variable provided to the object, a sum of the feedforward manipulated variable and the feedback manipulated variable.

3. The control apparatus according to claim 2, wherein the determinator acquires the control error data string while the feedback manipulated variable, among the feedforward manipulated variable and the feedback manipulated variable, is provided to the object via the adder.

4. The control apparatus according to claim 2, wherein the determinator acquires the response data string indicating the response characteristic while the specific manipulated variable is provided as the feedforward manipulated variable to the adder and the sum of the specific manipulated variable and the feedback manipulated variable is provided to the object via the adder.

5. The control apparatus according to claim 1, wherein the representative values are each an average value or a median value.

6. The control apparatus according to claim 1, wherein the determinator generates a second representative value data string constituted by representative values of the response characteristic of the object at the respective times based on a plurality of response data strings acquired over a plurality of times and determines a gain of the feedforward controller based on the representative value data string and the second representative value data string.

7. The control apparatus according to claim 6, wherein the determinator determines the second representative value data string based on a plurality of response data strings acquired over a plurality of times.

8. The control apparatus according to claim 1, wherein the determinator evaluates reproducibility of the plurality of control error data strings, generates the representative value data string in a case where the reproducibility does not meet a criterion, and determines a gain of the feedforward controller based on the representative value data string and the response data string.

9. The control apparatus according to claim 8, wherein the determinator evaluates the reproducibility based on at least two control error data strings of the plurality of control error data strings.

10. The control apparatus according to claim 9, wherein the determinator evaluates the reproducibility based on a total sum of absolute values of differences between the at least two control error data strings at the respective times.

11. The control apparatus according to claim 10, wherein, in a case where a count of times that the total sum meets a pass criterion exceeds a predetermined count, it is determined that the reproducibility meets the criterion.

12. The control apparatus according to claim 1, wherein the specific manipulated variable has a waveform having an impulse shape.

13. The control apparatus according to claim 1, wherein the object is a stage mechanism.

14. A positioning apparatus comprising:
a stage mechanism; and
the control apparatus according to claim 1, the control apparatus configured or operating to control the stage mechanism as the object.

15. A lithography apparatus that transfers a pattern of an original plate onto a substrate, the lithography apparatus comprising:
a stage mechanism that operates to align the original plate with the substrate; and
the control apparatus according to claim 1, the control apparatus configured or operating to control the stage mechanism as the object.

16. An article manufacturing method comprising:
transferring a pattern of an original plate onto a substrate by using a lithography apparatus including: a stage mechanism that operates to align the original plate with the substrate, and the control apparatus according to claim 1, wherein the control apparatus is configured or operates to control the stage mechanism as the object; and
obtaining an article by processing the substrate having undergone the transferring.
